(19) United States
(12) Patent Application Publication
(10) Pub. No.: US 2019/0378977 A1
(43) Pub. Date: Dec. 12, 2019

(54) FERROELECTRIC STRAIN BASED PHASE-CHANGE DEVICE

(71) Applicant: University of Rochester, Rochester, NY (US)

(72) Inventors: Stephen M. Wu, Rochester, NY (US); Wenhui Hou, Rochester, NY (US); Arfan Sewaket, Rochester, NY (US); Ahmad Azizimanesh, Rochester, NY (US)

(21) Appl. No.: 16/433,534

(22) Filed: Jun. 6, 2019

Related U.S. Application Data
(60) Provisional application No. 62/749,323, filed on Oct. 23, 2018.
(60) Provisional application No. 62/683,840, filed on Jun. 12, 2018.

(51) Int. Cl. H01L 45/00; H01L 27/24; H01L 27/1159

(52) U.S. Cl. CPC H01L 45/141; H01L 27/1159; H01L 27/2436; H01L 45/1206

(57) ABSTRACT

A phase transition optical device includes a substrate or a thin film of a ferroelectric material. A transition metal dichalcogenide is disposed over and in contact with the substrate or the thin film. The transition metal dichalcogenide has a semiconducting state with a first optical property and a semimetallic state with a second optical property. The semiconducting state or the semimetal state is selectable by applying a voltage across the ferroelectric material to induce a strain in the transition metal dichalcogenide via the ferroelectric material. A transistor device, integrated memory device, and a phase transition optical device are also described.

### CROSS-REFERENCE TO RELATED APPLICATIONS

This application claims priority to and the benefit of co-pending U.S. provisional patent application Ser. No. 62/683,840, FERROELECTRIC STRAIN BASED PHASE-CHANGE DEVICE, filed Jun. 12, 2018, and co-pending U.S. provisional patent application Ser. No. 62/749,323, FERROELECTRIC STRAIN BASED PHASE-CHANGE DEVICE, filed Oct. 23, 2018, both of which applications are incorporated herein by reference in their entirety.

### FIELD OF THE APPLICATION

The application relates to phase change devices and particularly to strain based state changes of phase change devices.

### BACKGROUND

The primary mechanism of operation of almost all transistors today relies on electric-field effect to induce band bending in a semiconducting channel so conductivity is tuned from the conducting ‘on’-state to a non-conducting ‘off’-state.

### SUMMARY

A phase transition device includes a substrate or a thin film of a ferroelectric material. A transition metal dichalcogenide is disposed over and in contact with the substrate or the thin film. The transition metal dichalcogenide has a semiconducting state and a semimetallic state. The semiconducting state or the semimetal state is selectable by applying a voltage across the ferroelectric material to induce a strain in the transition metal dichalcogenide via the ferroelectric material.

The phase transition device can include an electrical contact terminal disposed at either side of a strip of the transition metal dichalcogenide.

The phase transition device can be a field effect transistor.

The transition metal dichalcogenide can include a MoTe₂ material.

The ferroelectric material can include a single crystal of an oxide substrate of a relaxor ferroelectric material.

The ferroelectric material can includes a PMN-PT material.

A plurality of phase transition devices can be disposed in an integrated circuit.

In an absence of electrical power, a non-volatile phase transition device can remain in a previously selected state.

A transistor device includes a substrate or a thin film of a ferroelectric material having a first surface and a second surface. A gate terminal is electrically coupled to and disposed on the second surface. A section of a transition metal dichalcogenide is disposed over and in contact with the substrate or the thin film. The section of a transition metal dichalcogenide has a source terminal at a first end of the section of a transition metal dichalcogenide and a drain terminal at a second end of the section of a transition metal dichalcogenide. The section of a transition metal dichalcogenide has a semiconducting state and a semimetallic state. The semiconducting state or the semimetallic state is selectable by applying a voltage between the gate terminal and the source terminal or between the gate terminal and the drain terminal to induce a strain in the transition metal dichalcogenide via the ferroelectric material.

In an absence of electrical power, a non-volatile transistor device can remain in a previously selected state.

There is a substantially non-conducting path between the drain terminal and the source terminal in the semiconducting state.

There is a substantially conducting path between the drain terminal and the source terminal in the semimetallic state.

The phase transition device can be a field effect transistor.

The transition metal dichalcogenide can include a MoTe2 material.

The ferroelectric material can include a single crystal of an oxide substrate of a relaxor ferroelectric material.

The ferroelectric material includes a PMN-PT material.

In yet another embodiment, a plurality of transistor devices are disposed in an integrated circuit.

The plurality of transistor devices can include a sub nanosecond state change switching speed.

An integrated memory device includes a substrate or a thin film of a ferroelectric material having a first surface and a second surface. A plurality of non-volatile transistor devices remain in a previously selected state in an absence of electrical power. Each non-volatile transistor device includes a gate terminal electrically coupled to and disposed on the second surface. A section of a transition metal dichalcogenide is disposed over and in contact with the substrate or the thin film. The section of a transition metal dichalcogenide has a source terminal at a first end of the section of a transition metal dichalcogenide and a drain terminal at a second end of the section of a transition metal dichalcogenide. The section of a transition metal dichalcogenide has a semiconducting state and a semimetallic state. The semiconducting state or the semimetallic state is selectable by applying a voltage between the gate terminal and the source terminal or between the gate terminal and the drain terminal to induce a strain in the transition metal dichalcogenide via the ferroelectric material.

A phase transition optical device includes a substrate or a thin film of a ferroelectric material. A transition metal dichalcogenide is disposed over and in contact with the substrate or the thin film. The transition metal dichalcogenide has a semiconducting state with a first optical property and a semimetallic state with a second optical property. The semiconducting state or the semimetal state is selectable by applying a voltage across the ferroelectric material to induce a strain in the transition metal dichalcogenide via the ferroelectric material.

The first optical property can include a substantially opaque optical state, and the second optical property includes an at least translucent optical state.

### BRIEF DESCRIPTION OF THE DRAWINGS

The features of the application can be better understood with reference to the drawings described below, and the claims. The drawings are not necessarily to scale, emphasis instead generally being placed upon illustrating the principles described herein. In the drawings, like numerals are used to indicate like parts throughout the various views.

Images acquired by conductive atomic force microscopy are equivalent to photomicrographs which are accepted as images in patent applications.

FIG. 1A shows a schematic representation of an exemplary ferroelectric strain field effect device according to the Application;

FIG. 1B shows an optical micrograph of an actual MoTe₂ device on PMN-PT (011) according to the example;

FIG. 1C shows a graph of measured strain curves from strain gauges in x and y direction on PMN-PT with directions along crystal axes;

FIG. 1D shows a graph of strain induced transistor operation on a 13 nm MoTe₂ channel, with device W/L=2;

FIG. 2 shows a series of interrelated graphs of temperature cycling and non-volatile switching;

FIG. 3A shows a measurement of topography measured by conductive atomic force microscopy of the device of FIG. 2;

FIG. 3B shows a measurement of current measured by conductive atomic force microscopy of the device of FIG. 2;

FIG. 3C shows a CAFM measurement representing the initial condition;

FIG. 3D shows a CAFM measurement representing a pulse in the same direction as polarization;

FIG. 3E shows a CAFM measurement representing a pulse in the opposite direction as polarization;

FIG. 4A shows a CAFM measurement on a 50 nm MoTe₂ device;

FIG. 4B shows a drawing illustrating device operation based on contact metal induced strain;

FIG. 4C shows a graph of contact strain bias;

FIG. 4D shows a graph of channel conductance for MoTe₂ devices;

FIG. 5A shows a drawing of an exemplary 2D strain transistor in an open semiconductor state;

FIG. 5B shows device of FIG. 5A under a ferroelectric strain, where the device is in a closed, or metal state.

FIG. 6 shows a photomicrograph of a piezoresponse force microscopy (PFM) image of a section of PMN-PT (011) after quenching;

FIG. 7 shows a graph of Unipolar switching behavior on a MoTe₂/PMN-PT (011) device;

FIG. 8A shows a graph of output conductance in micro siemens (G_{DS}) plotted vs. electric field in kV/cm at 250 Kelvin;

FIG. 8B shows a graph of output conductance plotted vs. electric field at 275 K;

FIG. 8C shows a graph of output conductance plotted vs. electric field at 300 K;

FIG. 8D shows a graph of output conductance plotted vs. electric field at 325 K;

FIG. 9A shows a CAFM image of an exemplary device according to the Application;

FIG. 9B shows a corresponding finite element analysis simulation of the device of FIG. 9A;

FIG. 10A shows an atomic force micrograph of two 1T′-MoTe₂ flakes exfoliated onto a PMN-PT substrate;

FIG. 10B is a graph showing a height profile from the cross section in the AFM image from FIG. 10A;

FIG. 10C is a graph showing contrast values of cross section in the optical micrograph presented in the inset of FIG. 10A;

FIG. 11A is a graph showing a total contrast difference of a flake;

FIG. 11B is a graph showing a green contrast difference of a flake;

FIG. 11C is a graph showing a blue contrast difference of a flake;

FIG. 11D is a graph showing a red contrast difference of a flake;

FIG. 12 is a Table 1 showing calculated stress values of deposited contact metals through wafer curvature methods;

FIG. 13A is a photomicrograph of an exemplary gate controllable optical straintronic transistor before switching; and

FIG. 13B is a photomicrograph of the optical straintronic transistor of FIG. 13A after switching.

### DETAILED DESCRIPTION

In the description, other than the bolded paragraph numbers, non-bolded square brackets (“[ ]”) refer to the citations listed hereinbelow.

### Definitions

Electrical terminals as used herein are understood to include pads and any other suitable electrical connections to electrically couple structures of devices within an integrated structure.

As described hereinabove, the primary mechanism of operation of almost all transistors today relies on electric-field effect to induce band bending in a semiconducting channel so conductivity is tuned from the conducting ‘on’-state to a non-conducting ‘off’-state. Physical limitations to this type of operation exist since the rate at which the channel can be turned ‘on’ is limited by thermal effects at room temperature, where subthreshold swing is limited to 60 mV/decade, causing unacceptable leakage current when scaling [1, 2]. These transistors are also all volatile, because voltages on the gate electrodes need to be sustained for a conventional transistor to operate and information is lost upon powering down a device [3].

This Application describes a new and fundamentally different mechanism of operation, where a mechanical strain from a ferroelectric (FE) can be used to change the structural and electronic phase of the transition metal dichalcogenide (TMDC) MoTe₂. In a coupled TMDC/FE heterostructure, electric-field induced strain from the FE is transferred into the TMDC material to reversibly change the channel material from 2H—MoTe₂ (semiconducting) to 1T′-MoTe₂ (semimetallic). Using strain, large non-volatile changes in channel conductivity (Gₒₙ/G_{off}˜10⁷ vs. Gₒₙ/G_{off}˜0.04 in the control) can be achieved at room temperature. This new transistor structure and new fundamental mechanism for transistor switching potentially subverts many of the current physical limitations in the push for deeper scaling as current technologies reach the end of Moore's law [4, 5].

The TMDC class of materials is rich with various structural, optical, electronic, magnetic, and topological phases [6-9]. Within these TMDC class materials, it has been shown experimentally and theoretically that many are sensitive to strain [10]. Because 2D TMDC materials have exceptionally high elastic limits due to their strong in-plane covalent bonding relative to the out-of-plane Van der Waals bond, it is possible to apply as much as 25% reversible strain in certain 2D systems like graphene without film degradation unlike in 3D bonded systems [11]. Phase transitions between two distinct phases of 2D TMDC materials at these high strains have been examined as well. Particularly interesting is the transition between the semimetallic 1T′-MoTe₂ state and the semiconducting 2H—MoTe₂ state. Through engineering strain in this system, it has been both theoretically predicted and experimentally confirmed that such a transition takes place [12,13].

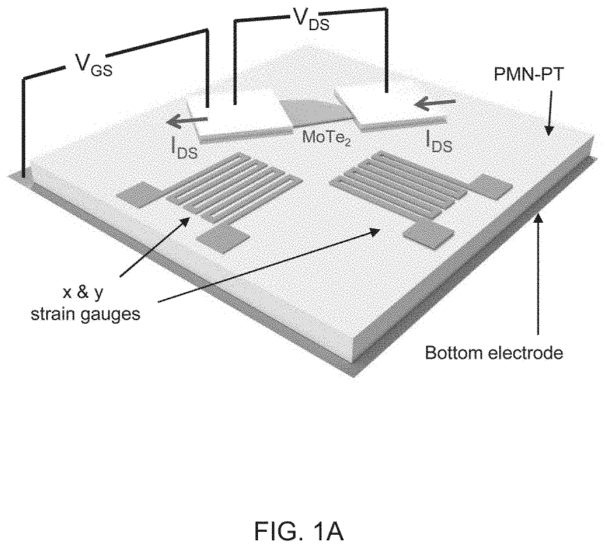

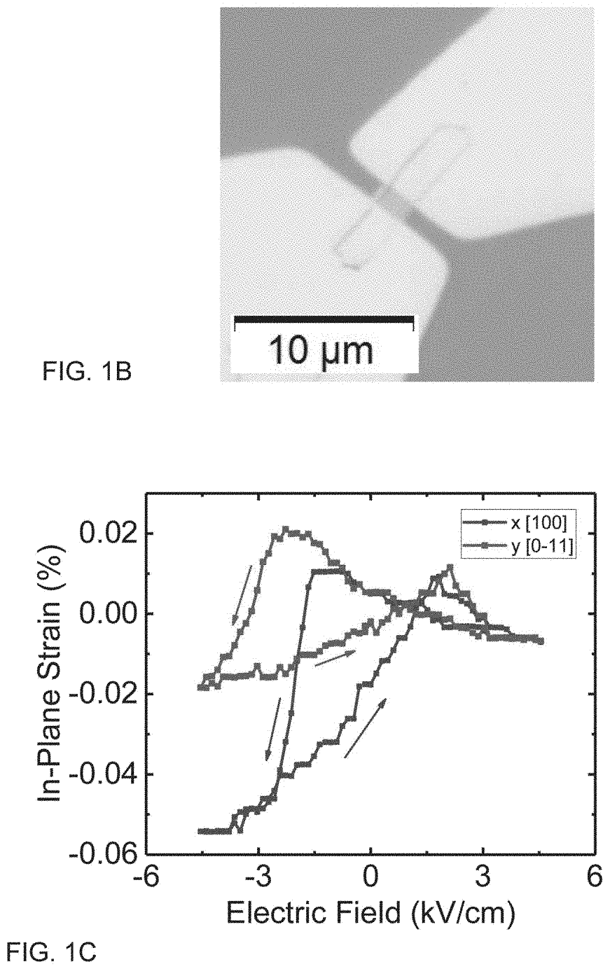

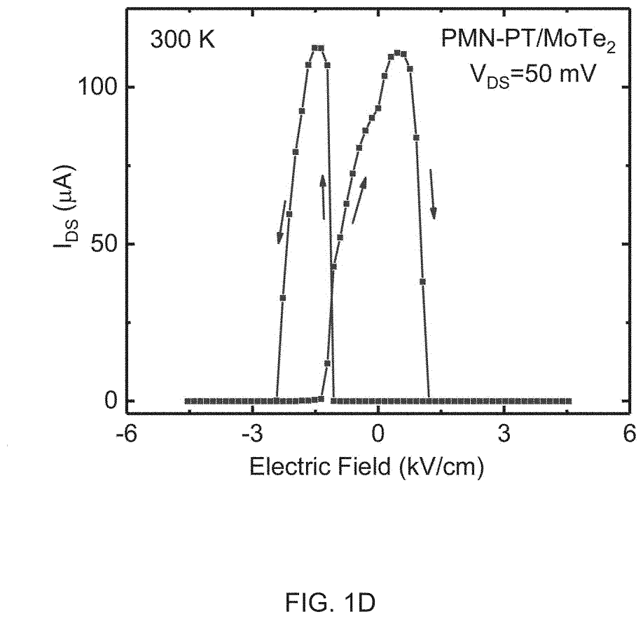

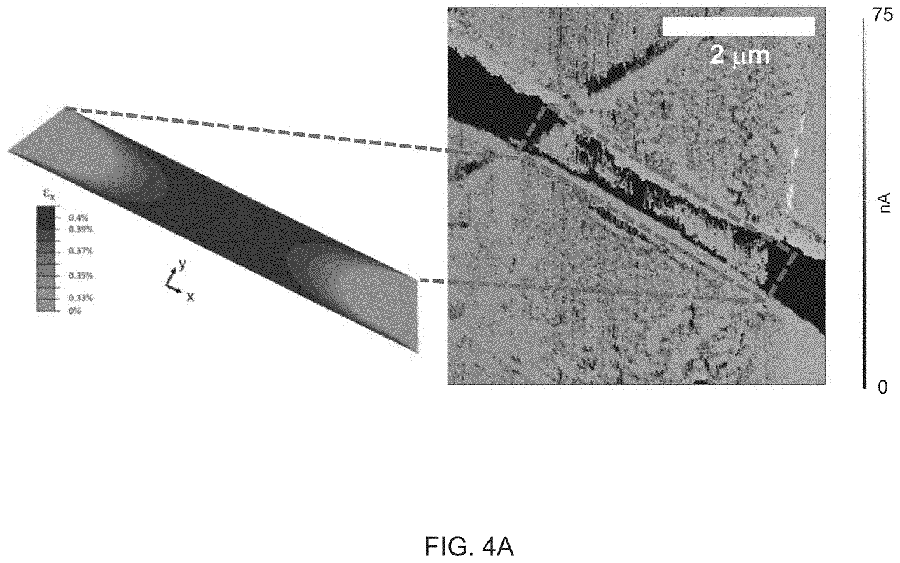

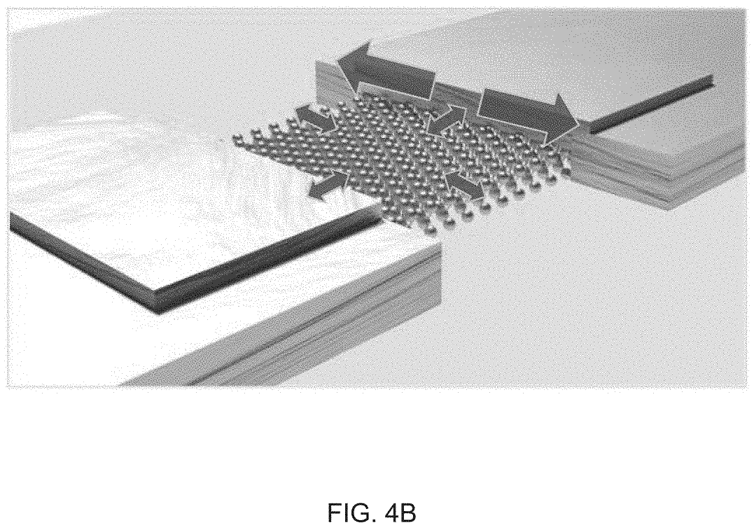

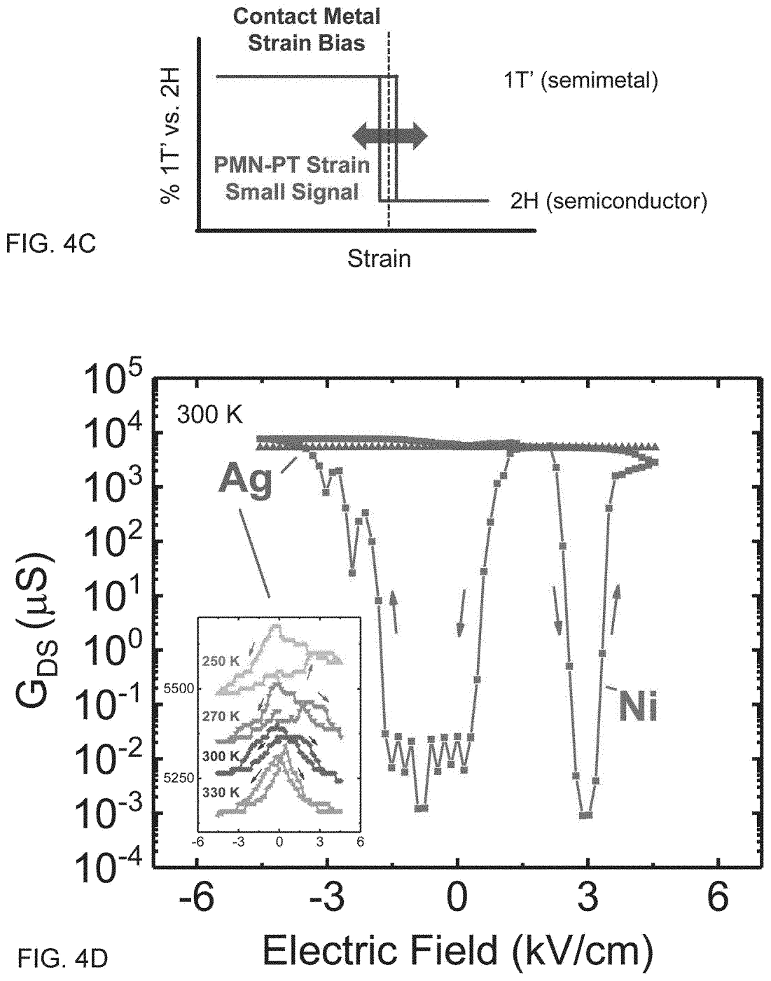

One challenge is to realize this phase transition in a realistic electronic device, because previous studies have only shown such phase transitions to occur through scanning probe studies. The largest obstacle being the small amount of strain available that is reversible and electrically controllable. It was realized that we could overcome this obstacle through gate-controllable strain from ferroelectric single crystals (FIG. 1A), and strain engineering through thin film stress (FIG. 4B).

FIG. 1A shows a schematic representation of an exemplary ferroelectric strain field effect device according to the Application. Here, gate voltage across the ferroelectric not only induces an electric polarization across the channel, but also induces a strain that drives a phase transition between semimetallic and semiconducting. This fundamentally different mechanism for operation does not rely on electrostatic charge accumulation as in conventional field effect transistors, and therefore does not suffer from any of the same subthreshold slope limitations, opening the possibility to a scalable, fast, low-power, non-volatile technology that has large implications for both high-density non-volatile memory and logic.

### Example

An exemplary device according to FIG. 1A can use single crystal oxide substrates of relaxor ferroelectric Pb(Mg_{1/3}Nb_{2/3})_{0.71}Ti_{0.29}O₃ (PMN-PT), with a Au (100 nm)/Ti (5 nm) bottom gate electrode for ferroelectric switching. On top of this ferroelectric substrate 1T′-MoTe₂ was exfoliated from a single crystal source grown in the metastable 1T′ phase, which is stable at room temperature. Individually patterned contact pads were fabricated by direct write laser photolithography for each of the relevant exfoliated MoTe₂ flakes, chosen to have a variety of thicknesses ranging from 12 nm to 70 nm (FIG. 1A, FIG. 1B).

FIG. 1B shows an optical micrograph of an actual MoTe₂ on PMN-PT (011) device according to the example. Film thicknesses were verified using contrast variation in optical microscopy and checked against atomic force microscopy measurements. At the point of exfoliation, the strain state in the MoTe₂ layer is zero. Depending on the contact material, stress from the deposited thin film strains the MoTe₂ channel at the contact pads, analogous to the uniaxial strain techniques from strained silicon technology, widely adopted in industrial CMOS processes [14]. The contact metal stress is important for obtaining a functional device.

During fabrication we were careful not to increase the temperature of the ferroelectric above 80° C., well below the Curie temperature of the ferroelectric at 135° C. Upon reaching the Curie temperature, the sudden quenching through the transition will cause the size of the domains to shrink from the few micron scale to the nanometer scale [15, 16], setting a complicated strain state within the MoTe₂. (See also: supplementary information hereinbelow). Devices of the same approximate size as a characteristic single ferroelectric domain play a role in seeding our transitions.

The strain in the system was characterized by micropatterning directional strain gauges on the ferroelectric surface and characterize the electrical properties of the MoTe₂ device using standard transfer curve measurements (FIG. 1A).

FIG. 1C shows a graph of measured strain curves from strain gauges in x and y direction on PMN-PT with directions along crystal axes. Strain from the ferroelectric was measured through strain gauges on a representative (011) oriented PMN-PT single crystal polished to ˜0.5 nm surface roughness (FIG. 1C), showing that we can apply enough electric field to switch the strain state of the ferroelectric. Because the size of the strain gauges are large relative to the individual domain structure of the ferroelectric (100 μm vs. 1 μm) an aggregate strain effect can be seen in both the x and the y direction, showing tensile strain near the coercive field of the ferroelectric, and compressive strain elsewhere. The asymmetry in the strain curves is due to the well-known effect of defect dipoles in ferroelectric systems, causing an internal electric field bias effect [17-23]. Strain gauge measurements are only a representative measure of strain because the strain of each individual MoTe₂ flake feels is strongly dependent on the polarization of the ferroelectric domain the flake is exfoliated onto, setting the initial starting ‘zero strain’ state [24].

To test the effect of strain on our devices we pattern an exfoliated flake of 13 nm 1T′-MoTe₂ with 35 nm Ni contact pads, which applies a measured in-plane tensile stress of 0.58 GPa to MoTe₂ at the contacts. (See also: supplementary information hereinbelow).

FIG. 1D shows a graph of strain induced transistor operation on a 13 nm MoTe₂ channel, with device W/L=2. The measured transfer characteristics on a linear scale are shown in FIG. 1D, which shows a reversible room-temperature on-off switching behavior that matches the standard strain butterfly curve in ferroelectric materials (FIG. 1C). Substantial changes (>1 order of magnitude) were observed in channel conductivity in over 10 other MoTe₂ devices of various thicknesses on various PMN-PT (011) substrates as well as similar bipolar effects.

The strain driven conductivity changes occurred in several devices after multiple sweeps of gate electric field and repeated for several cycles afterwards in a stable state after training. The bipolar nature of channel current with respect to electric field strongly suggests a strain driven transition between the 1T′ and 2H phases of MoTe₂, where the strain in the MoTe₂ flakes evolves with applied gate voltage across the ferroelectric.

To further examine the phase transition in these devices, temperature dependent measurements of channel conductivity were performed in a separate MoTe₂ device with a nominal thickness of 70 nm, using a separate PMN-PT (011) substrate with 35 nm Ni contact electrodes. An optical micrograph of the actual measured device is shown in FIG. 1B.

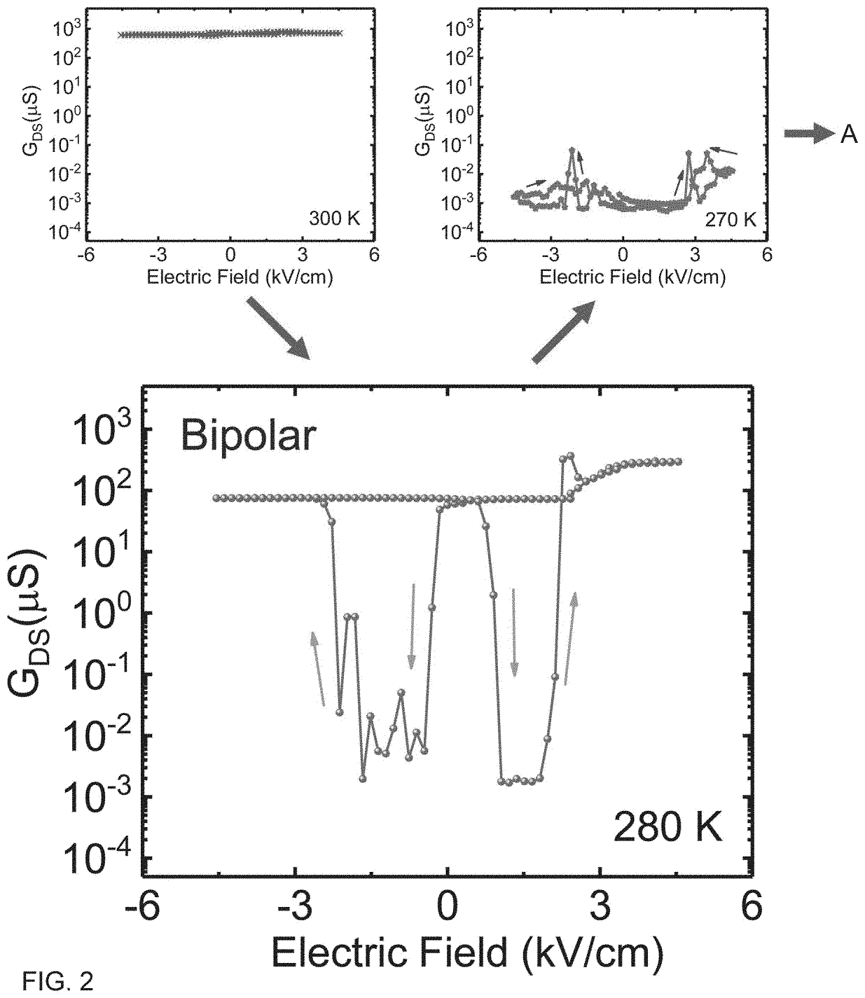

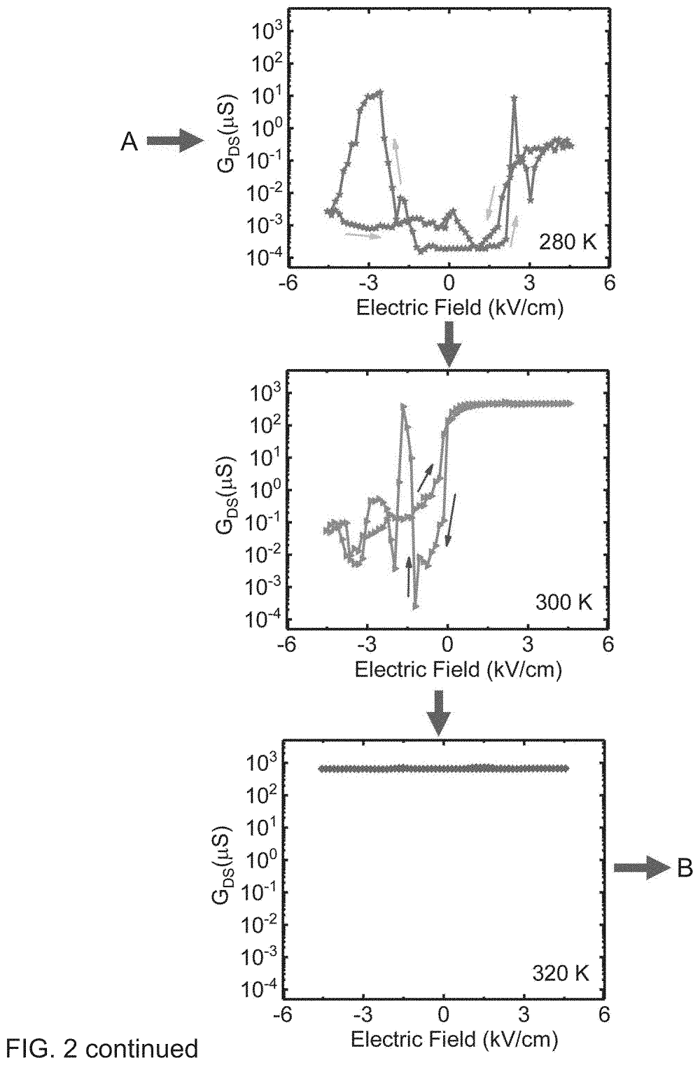

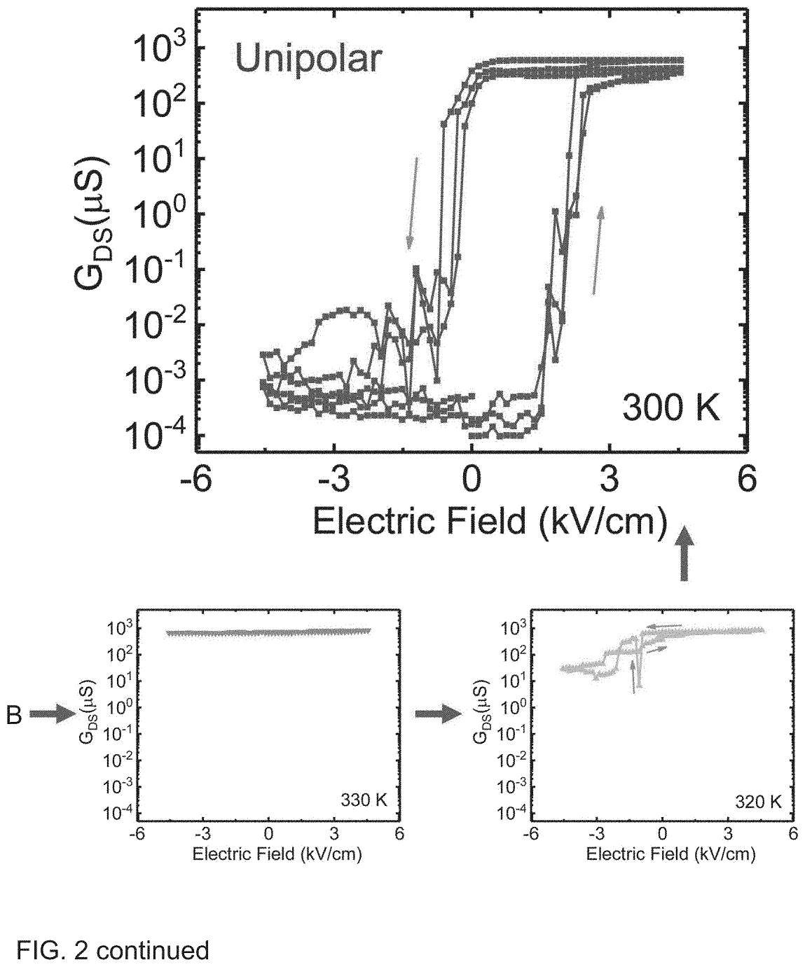

FIG. 2 shows a series of interrelated graphs of temperature cycling and non-volatile switching. Log-scale channel conductance measurements for the device are shown in FIG. 1B (70 nm channel, W/L=2.3) with respect to temperature cycling, initially starting at 300 K then to 270 K to 330K to 300 K. Measurements were taken with V_{DS}=100 mV and are current limited at 100 μA. Transitions between full 1T′ metallic state, and Schottky barrier are limited operation in the 2H state is shown. Depending on the temperature history, large variations in device behavior existed due to strain evolution and temperature dependence of the phase transition. Both bipolar and unipolar (non-volatile) behavior within the devices were seen. The final exemplary unipolar device at a single temperature was robust as shown by three full major loop sweeps. (See also: Additional data on temperature dependence and unipolar behavior in the supplementary information hereinbelow).

Log-scale conductivity is shown in FIG. 2, showing a unique temperature evolution as we sweep from 300 K to 270 K to 330 K and back to 300 K. Both bipolar and unipolar (non-volatile) channel conductivity modulation was observed, with a maximum Gₒₙ/G_{off}˜6.2×10⁶ in the final 300 K state, which is a larger value than any 2H—MoTe₂ field-effect transistor using any contact scheme for any thickness [25-27]. For a channel thickness of 70 nm, representing ˜100 layers of MoTe₂, conventional field effect conductivity modulation is limited to less than 1 order of magnitude due to electric field screening in the semiconductor [28]. By purposely choosing a contact metal that exhibits Schottky contact behavior with 2H—MoTe₂, our ‘off-state’ becomes two back-to-back Schottky diodes exhibiting low current when bias voltages are kept below the Schottky barrier height. Because crystal orientation of the PMN-PT relative to the crystal structure of the MoTe₂, or the PMN-PT domain structure, are not controlled for, it is understandable why device to device variation may occur since strain directionality may play a large role in seeding the phase transition [12, 24]. These uncontrolled factors lead to variation in bipolar modulation behavior, where FIG. 2 shows the opposite result of FIG. 1C, FIG. 1D. The unique temperature hysteresis within this device can be understood from the prospective that the phase boundary with respect to strain is highly temperature dependent, which has been measured in the past in 2H—MoTe₂ suggesting the 2H phase is more favorable at low temperatures [13]. Also, strain within the MoTe₂ from both the substrate and the contacts is itself temperature dependent, as temperature dependent measurements with our strain gauges confirmed. This temperature dependence is due to differential thermal contraction, thin film stress relaxation with respect to temperature, temperature dependence of the piezoelectric coefficient in PMN-PT, and stress working with respect to ferroelectric strain. Unipolar behavior arises from the same defect dipole contribution that causes strain asymmetry in our measured strain gauge devices. This unipolar behavior can also be achieved without internal electric field bias through asymmetric electric field sweeping in PMN-PT, having been well studied in the past in various materials coupled to PMN-PT [20-23].

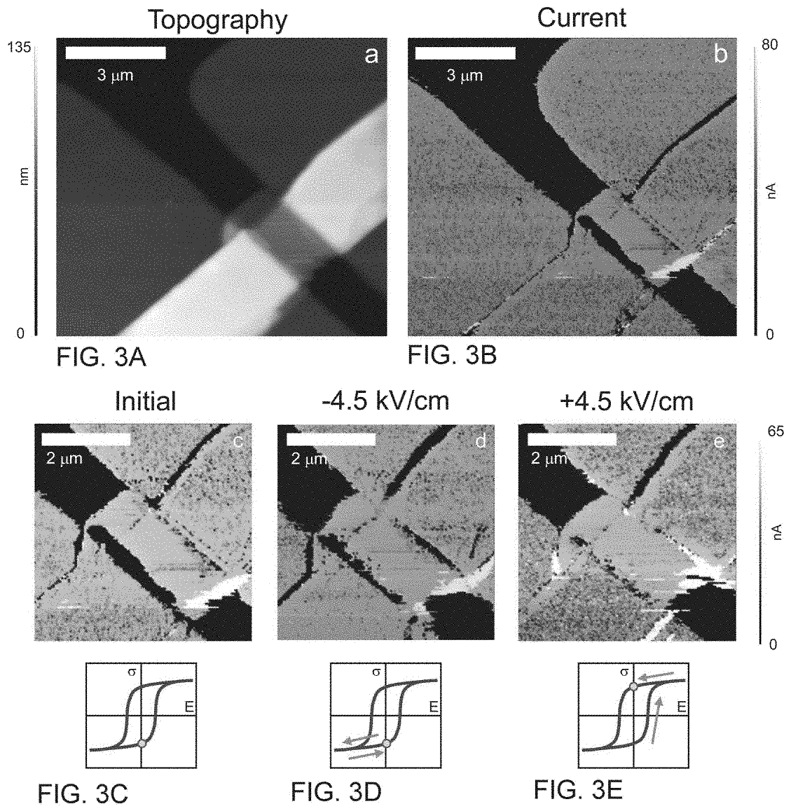

FIG. 3A to FIG. 3E show exemplary measurements using conductive atomic force microscopy of switching behavior of an exemplary device according to FIG. 1A. FIG. 3A shows a photomicrograph of topography measured by conductive atomic force microscopy of the device of FIG. 2 after being left in the 2H state (290 K). FIG. 3B shows a measurement of current measured by conductive atomic force microscopy of the device of FIG. 2 after being left in the 2H state (290 K). Large changes in conductivity can be inferred from CAFM data near the contact edges. FIG. 3C to FIG. 3E show exemplary measurements of CAFM images after a pulse sequence. FIG. 3C shows a CAFM image representing the initial condition. FIG. 3D shows a CAFM image representing a pulse in the same direction as polarization, and FIG. 3E shows a CAFM image representing a pulse in the opposite direction as polarization. Channel near contact edges stay low conductivity for FIG. 3D, while the edges go higher conductivity after the opposite pulse FIG. 3E.

To directly view a real space image of the channel under ferroelectric strain, conductive AFM (CAFM) was used to directly probe channel conductivity. FIG. 3C to FIG. 3E show the results of CAFM scans of the device shown in FIG. 2 directly after measurement (left in the low conductivity state) with both contact pads grounded with respect to the voltage biased CAFM tip. A large non-conductive area is found near the contact edge of the device representing the 2H phase of MoTe₂ and hinting at effects arising from contact metal induced strain. The effect of strain on this channel was further observed by applying a gate voltage pulse to set the conductivity state of the channel as schematically represented by the hysteresis loops in FIG. 3C-FIG. 3E. The gate is first pulsed in the same direction that the device is already set in, as a control measurement, and in FIG. 3D it was found that the large non-conducting region at the contact edge is retained but is now also mirrored at the other contact edge as well. The initial asymmetry of the CAFM image (FIG. 3C) is due to gate voltage being applied with respect to the source contact from the measurement in FIG. 2, whereas the first and second pulse (FIG. 3D, FIG. 3E) are applied with respect to both source and drain. Next a pulse was applied in the positive direction to switch the channel to the conducting state and in FIG. 3E it was found that the non-conductive regions near the contacts now close. This suggests that the strain driven phase transition is seeded by strain from the thin film stress induced by the contacts.

FIG. 4A-FIG. 4D show CAFM measurements, drawings, and graphs of the effect of contact metals and simulations. FIG. 4A shows a CAFM measurement on 50 nm MoTe₂ device (W/L=6.3) patterned with Ni contacts on PMN-PT (111) oriented single crystal and corresponding contour graph showing contact edge effects. Data is shown with finite element analysis simulation of strain in the channel assuming clamped tensile strain from the contact metal. FIG. 4B shows a drawing illustrating device operation based on contact metal induced strain, where electric field controllable strain from PMN-PT (111) is used to modulate on top of contact induced strain. A proposed mechanism of operation of strain-biased PMN-PT device is also described. FIG. 4C shows a graph of contact strain bias. FIG. 4D shows a graph of channel conductance on MoTe₂ devices with Ag (low compressive stress, ˜0.2 GPa) and Ni (larger tensile stress, 0.58 GPa) contacts. Only small modulation in conductivity is seen in Ag contact devices (˜4%) versus Ni devices (˜10⁹%). Inset represents a temperature evolution of a Ag contact device.

The effect of substrate crystal orientation and contact metals on the behavior of devices described hereinabove were further investigated by exploring more MoTe₂ devices on PMN-PT (111) substrates. FIG. 4A shows the same current map measured through CAFM on a MoTe₂/PMN-PT (111) device with the same 35 nm Ni contacts, showing the same characteristic phase change behavior at the contact edges but on a device with a shorter channel. Our contact strain hypothesis is supported by a finite element analysis simulation of the strain state within a MoTe₂ channel given tensile strain from the edges, showing the same characteristic shape as the current map. Further modeling done on a longer channel device, similar to the device shown in FIG. 3A, shows the same correspondence. (See also: supplementary information hereinbelow). Using both models, with the calculated strain induced into the MoTe₂ channel from contact induced stress (using literature values for MoTe₂ Young's modulus and Poisson's ratio [13]), and the characteristic size of the 2H region as measured by CAFM at the contact edge, the approximate threshold for the phase transition can be extracted. The contacts were found to apply tensile strain to the MoTe₂ at 0.4%, and the strain threshold occurs at approximately 0.33% based off the length scale that the 2H region bleeds out at the Ni contacts. The magnitude of this strain is comparable with both experimentally observed and theoretically predicted strain transitions in 2H—MoTe₂ [12, 13], as well as with the amount of electric field controllable strain in PMN-PT as measured in FIG. 1C. Strain from individual domains may be larger than the aggregate strain measured in our representative strain gauge measurements. Theoretical predictions start with the stable 2H state at 0% strain instead of the metastable 1T′ state, thus leading to many of the observed differences in our devices versus published theory. Because these devices were patterned on PMN-PT (111), it suggests that phase transitions are robust against ferroelectric orientation. To our best current understanding, these microscale devices do not depend heavily on the overall aggregate strain behavior of the ferroelectric single crystal, but on the individual ferroelectric domains that the MoTe₂ channel and contacts land on [24].

Using different contact metals on PMN-PT (111) phase transitions have been shown to be robust when contact metals apply a finite tensile stress (Ni). When compared to low stress contacts (˜0.2 GPa) made of 50 nm Ag, conductivity changes are limited to few percent range at all temperatures compared to a similar Ni device which has conductivity changes ˜10⁹% (FIG. 4b). Out of 13 measured devices with Ag contacts on both PMN-PT (011) and (111) oriented substrates, no device showed any meaningful conductivity modulation other than a marginal few percent change.

The overall predicted mechanism of operation based on our experimental devices is outlined in FIG. 4A. Thin film stress from contact metal deposition sets a higher strain state than a single ferroelectric can apply by itself, while a small amount of electric-field controllable strain from PMN-PT can bring the MoTe₂ across the phase boundary. This suggests that the majority of the channel conductivity changes happen underneath the contacts and our CAFM measurements are only able to incidentally observe phase transitions at the edges in special cases. This is supported by the fact that no CAFM measurement on any device showed channel conductivity changes further than 250-500 nm away from the contact edges. The use of metastable 1T′-MoTe₂ as the starting material allows the two contact sides to always be connected through a metallic link, such that large changes that occur near the contacts are reflected in the final electrical measurement. Phase transitions were not observed when using 2H—MoTe₂ as the starting material with Ni contacts, although presumably through thin film strain engineering it can become possible in a different geometry. We also note that while the majority of the devices had large changes in conductivity, approximately 8 out of 28 measured devices on both (011) and (111) PMN-PT using Ni contacts also had low modulation in the few percent range [⅓ on (111), ¼ on (011)]. We attribute this variation to the various uncontrolled aspects of our devices: whether each MoTe₂ flake would land on single or multiple ferroelectric domains, what the polarization of the domain was (setting the zero strain starting state) [24], which direction the ferroelectric strain exists in with respect to the contact metal, and what the crystal orientation of the MoTe₂ was when exfoliated. Further strain engineering on MoTe₂/ferroelectric devices can account for such factors to increase reproducibility, reliability, and device yield.

Methods

Device Fabrication: The exemplary devices described hereinabove were generally fabricated on PMN-PT single crystals with sputtered Au (100 nm)/Ti (5 nm) bottom electrode contacts. Commercially purchased 1T′-MoTe₂ (HQ Graphene) was exfoliated onto the polished (Rₐ˜0.5 nm) side of PMN-PT using a Nitto Semiconductor Wafer Tape SWT10. Optical contrast thickness identification was used to characterize thickness of flakes. Direct-write laser photolithography was performed using a Microtech LW405 laserwriter system, with S1805 photoresist that is specifically soft baked at low temperatures (80° C.) to prevent heating above the Curie temperature. If standard bake recipes for photoresists and e-beam resists are used, spontaneous quenching through the Curie temperature will occur, and result in devices that do not produce larger than a few percent conductance modulation. Patterns were exposed using standard photolithographic doses of 300 mJ/cm², and photoresist was soaked in chlorobenzene for 5 minutes before development for undercut control. All contact metals were deposited using e-beam evaporation at 5×10^{-s} torr pressure at a rate of 1 Å/s. Strain gauges were constructed from the same thin film deposition (35 nm Nickel), and separately calibrated using flexible Kapton substrates with strain applied through bending. Axial and transverse gauge factors are measured to be 3.1 and 0.15 respectively, limiting the contributions of strain perpendicular to the axial direction by over a factor of 20.

Device Characterization: Devices were generally characterized using low-frequency AC lock-in techniques (3 Hz) with AC voltage signal provided by a separate phase locked function generator. Measurements of conductivity were done with a 100 μA current limiting circuit to prevent device blow-out since the high conductivity states are purely metallic and large current densities can form when the transition from 2H to 1T′ occurs. Gate voltages were applied between the backgate and the source contact in the device using a DC power supply and typically applied for 5 seconds before each conductivity measurement.

Conductive Atomic Force Microscopy (CAFM): Devices were measured using conductive tips coated using confocal DC sputtering of 10 nm W, followed by 20 nm Pt. Measurements were performed in contact mode, with force setpoint low to prevent sample damage upon scanning. Pulse measurements were done by removing the device from the AFM, ramping voltage on the gate relative to both grounded contact pads over 30 s and then ramping down to 0 V. Devices were then placed back into the AFM for the next CAFM measurement.

Finite Element Analysis: Finite element analysis was performed using Abaqus FEA software suite. A membrane with the same size of the thin film was modeled by quadratic plane elements, with average side length of 0.05 μm. Lateral strain of 0.4% was applied to the contact edges to model Ni interface strains. Side edges are free. The material was assumed to be isotropic by averaging anisotropic mechanical properties. Color coding of resulting strain contours was set to show the range where switching is expected based on the strain analysis described on the main text.

Method of Operation for Complex Oxide/2D Materials Heterostructures: Strain Controlled Phase Transitions for Nanoelectronics

A strain-induced phase-change transistor, through heterointerfacial coupling between 2D transition metal dichalcogenides (TMDCs) and ferroelectric oxide thin films has been described hereinabove. By exploiting TMDC materials close to structural and electronic phase transitions, it is possible to fabricate a new type of non-volatile transistor where a 2D channel can be converted reversibly from metal to semiconductor under the application of strain from ferroelectric oxides. This type of device combines the best properties of ferroelectric oxides, such as low-power operation, fast-switching speeds, and non-volatility, with the rich variety of structural, electronic, magnetic, and topological phases available in the TMDC family.

“Straintronics” based on 2D materials can sidestep many of the problems associated with conventional field effect transistor technology such as current leakage, small on-off ratios, and low subthreshold slopes while providing a non-volatile mechanism for switching that would lead to advances in low-power memory and gate-controllable exotic states of matter.

The new technology of the Application uses gate-controllable strain in a transistor structure to reversibly turn a channel from semiconductor (off) to semimetallic (on). For example, in some embodiments, a 2D MoTe2 is stretched or compressed on-chip using a ferroelectric dielectric to seed the phase transition between the two states. This is a low-power, non-volatile, high-speed, reversible technique to supplant conventional CMOS technology.

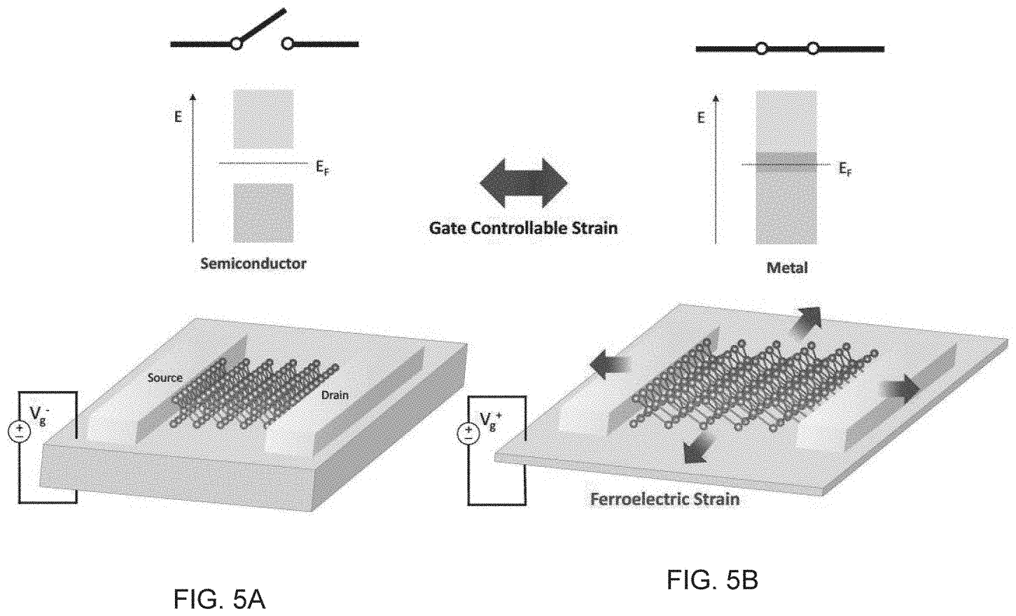

FIG. 5A shows a drawing of an exemplary 2D strain transistor in an open semiconductor state. FIG. 5B shows device of FIG. 5A under a ferroelectric strain, where the device is in a closed, or metal state.

In conclusion, we have described and taught hereinabove, a new type of transistor that operates outside of conventional field effect transistor technology, where electric-field induced strain can reversibly change the device from semimetallic to semiconducting. Strain induced phase changes do not suffer from the same limitations as conventional field effect transistors in terms of obtaining large on-off ratios while retaining fast switching outside of subthreshold slope limitations. The ‘on-state’ of our device is fully metallic leading to exceptionally high on-currents, while the ‘off-state’ can be engineered for small current leakage through contact engineering. Because the devices do not heavily depend on the thickness of the MoTe₂ channel and retains the three-terminal gate configuration from conventional field effect transistors, the process to scale these devices into realistic commercial integrated circuits becomes significantly less challenging. This type of ‘straintronic’ device, combines the best properties of 2D materials (large elastic limit, immunity to strain induced breakage, wide variety of phases) with the best properties of ferroelectrics (low-power, non-volatile, fast switching). Nanoelectromechanical relay devices similarly operate on mechanical principles but suffers from high-power and reliability issues [24], both of which are side-stepped by using a super-elastic material and a low-power ferroelectric to apply strain. Ferroelectric devices can reach sub-ns non-volatile strain switching at the sub-attojoule/bit level [29-32]. Moreover, looking beyond MoTe₂, using strain engineered 2D materials with ferroelectrics represents a fundamentally exciting platform to explore the wide variety of other electric-field induced phase transitions in the 2D materials world (i.e. magnetic [33, 34], topological [35, 36], superconducting [37], etc.), opening the door to various gate-controllable exotic states of matter.

The new straintronic transistors described hereinabove are suitable for integration, including high density integration high speed operation (nano-second (ns) and sub ns) for use in any suitable type of integrated circuits, typically digital integrated circuits ranging from custom gate arrays or logic elements to multi-core processors. It is generally expected that these new straintronic transistors using a variety of any suitable materials can replace substantially any existing bipolar technologies, or FET technologies ranging, for example, from the earliest CMOS processes to the most recent FinFETs. Beyond density and speed, the new straintronic transistors are also inherently non-volatile even in absence of circuit electrical power.

Supplementary Information

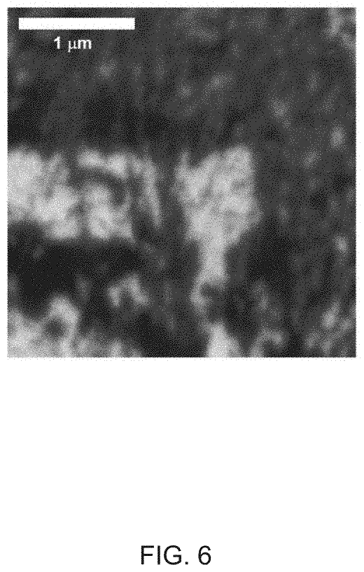

FIG. 6 shows a piezoresponse force microscopy (PFM) image of a section of PMN-PT (011) after quenching through the Curie temperature from 150° C. with 10 Vₚₚ excitation on-resonance at 280 kHz. Out-of-plane contrast in PFM phase shows formation of nanoscale ferroelectric domains within larger micron sized domains. The formation of these nanodomains is consistent with the domain evolution of PMN-PT single crystals from literature[15, 16] and leads to a non-uniform strain state within MoTe₂ devices. Common device processing techniques typically require heating near the Curie temperature, which we avoid by using a low temperature soft-bake with standard photolithographic photoresists.

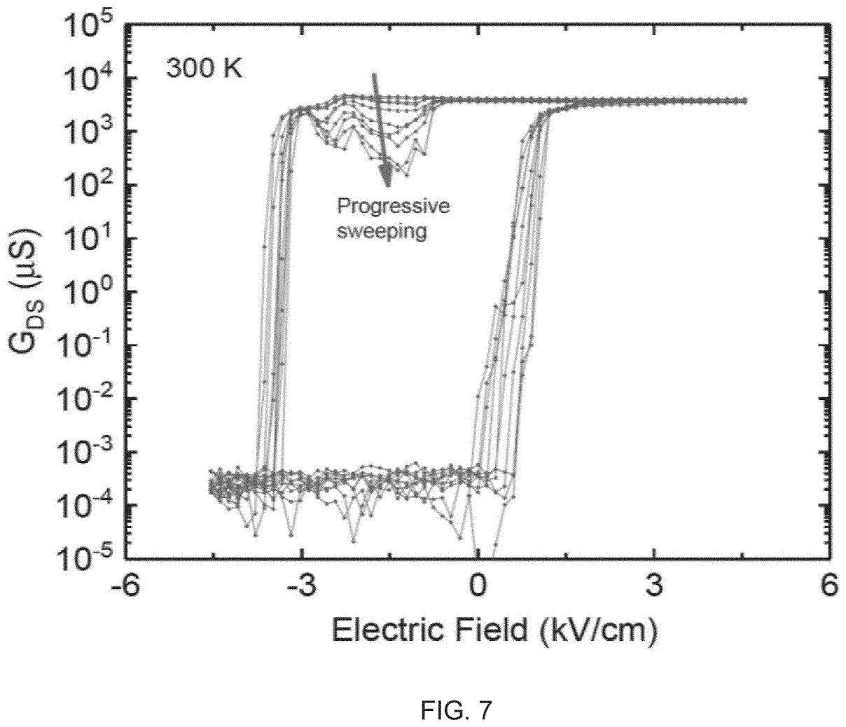

FIG. 7 shows a graph of Unipolar switching behavior on a MoTe₂/PMN-PT (011) device (17 nm MoTe₂ thickness, W/L=3.25), separate to the data described hereinabove, showing ten full gate voltage sweeps. Behavior is after temperature sweep from 250 K to 325 K and back to 300 K. With progressive sweeping, a dip within the transfer characteristics begins to grow, likely due to the evolution of strain within this device.

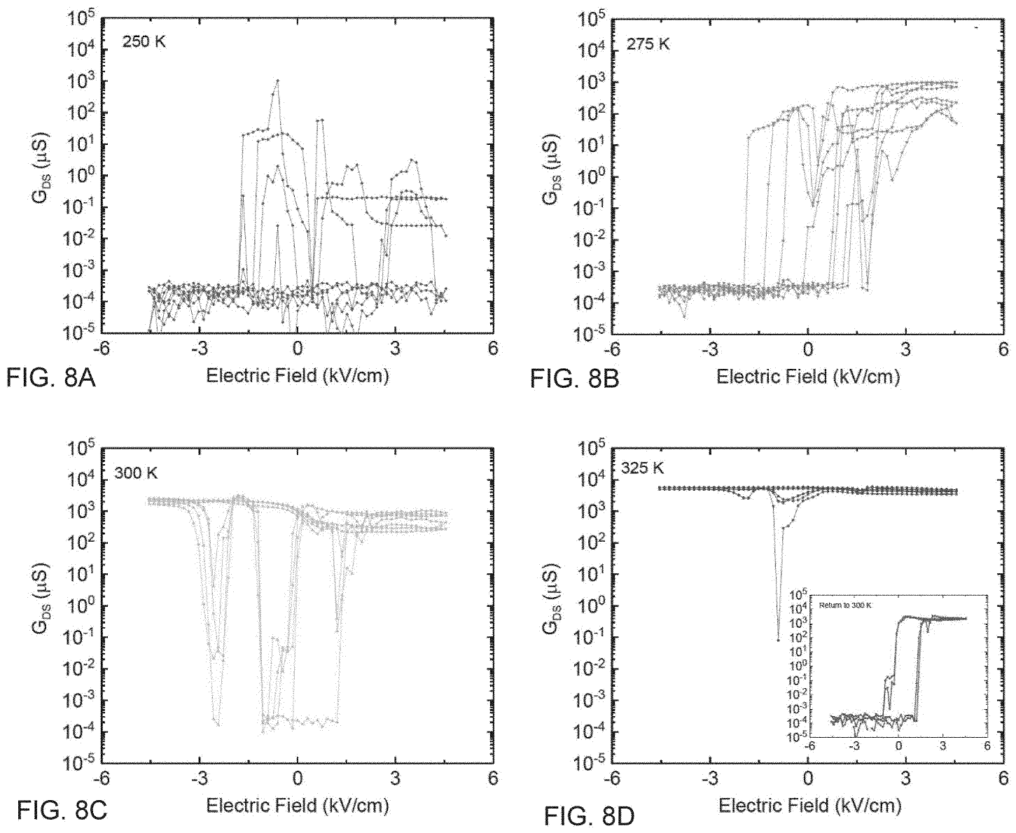

FIG. 8A-FIG. 8D show temperature dependent transfer characteristics on MoTe₂/PMN-PT (011) device (42 nm MoTe₂ thickness, W/L=3.92), separate to the data described hereinabove.

The exemplary device shown in FIG. 8A-FIG. 8D was swept from 250 K to 325 K, and back to 300 K. FIG. 8A shows a graph of output conductance in micro siemens (G_{D}s) plotted vs. electric field in kV/cm at 250 Kelvin. FIG. 8B shows a graph of output conductance plotted vs. electric field at 275 K. FIG. 8C shows a graph of output conductance plotted vs. electric field at 300 K. FIG. 8D shows a graph of output conductance plotted vs. electric field at 325 K. The final unipolar device characteristics are shown in FIG. 8D. Four full gate voltage sweeps are shown at each temperature, representing the steady state behavior of the device after two initial training sweeps (not shown for clarity). Device behavior at some temperatures continues to evolve with each progressive sweep showing a unique strain evolution within the device. Behavior described here is also seen in data from devices described hereinabove, suggesting a temperature dependent phase transition between the 2H and 1T′ phases of MoTe₂, with the 2H phase favored at low temperatures.

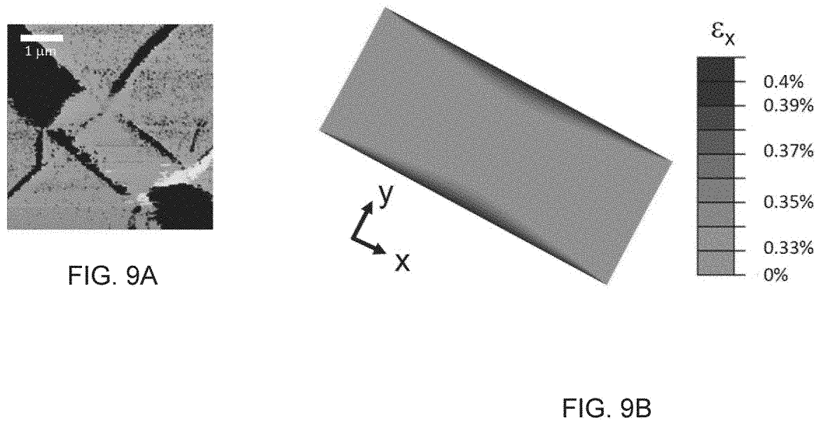

FIG. 9A shows a CAFM image of an exemplary device according to the Application. FIG. 9B shows a corresponding finite element analysis simulation of the device of FIG. 9A. Finite element analysis simulation of a rectangular channel device with contact pad induced strain clamped at 0.4%, presented with the CAFM image from FIG. 8D reproduced. The characteristic features of the 2H region near the contacts are reproduced in the simulation. Simulations can provide an estimate as to how much strain is needed to seed the transition by matching the length scale of the observed 2H transition from CAFM images to the strain from simulations. From our data, it is estimated that the strain cutoff between 2H and 1T′ phases is 0.33% tensile strain, which is represented in the simulation figure as a hard cutoff in color.

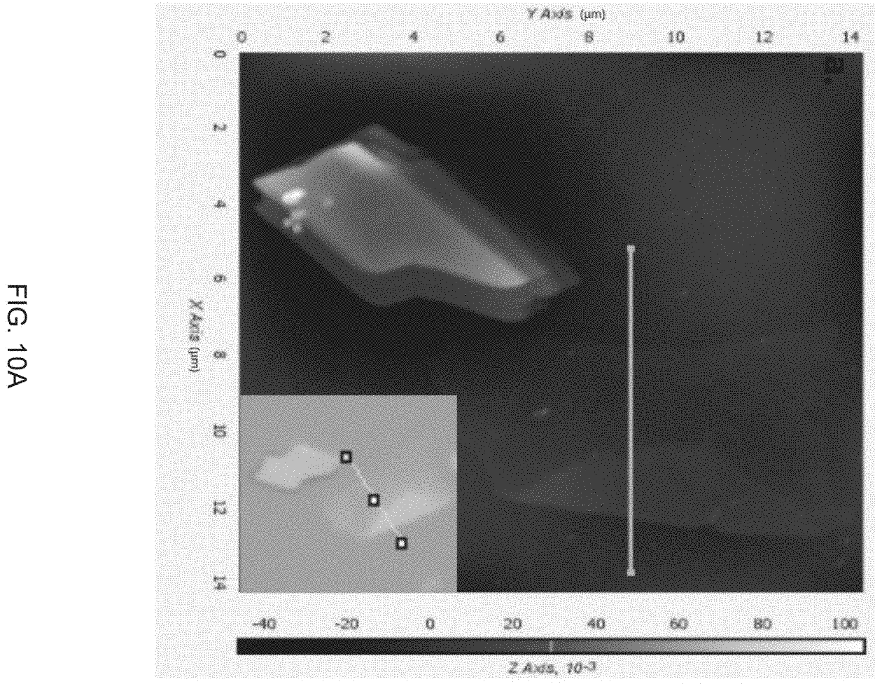

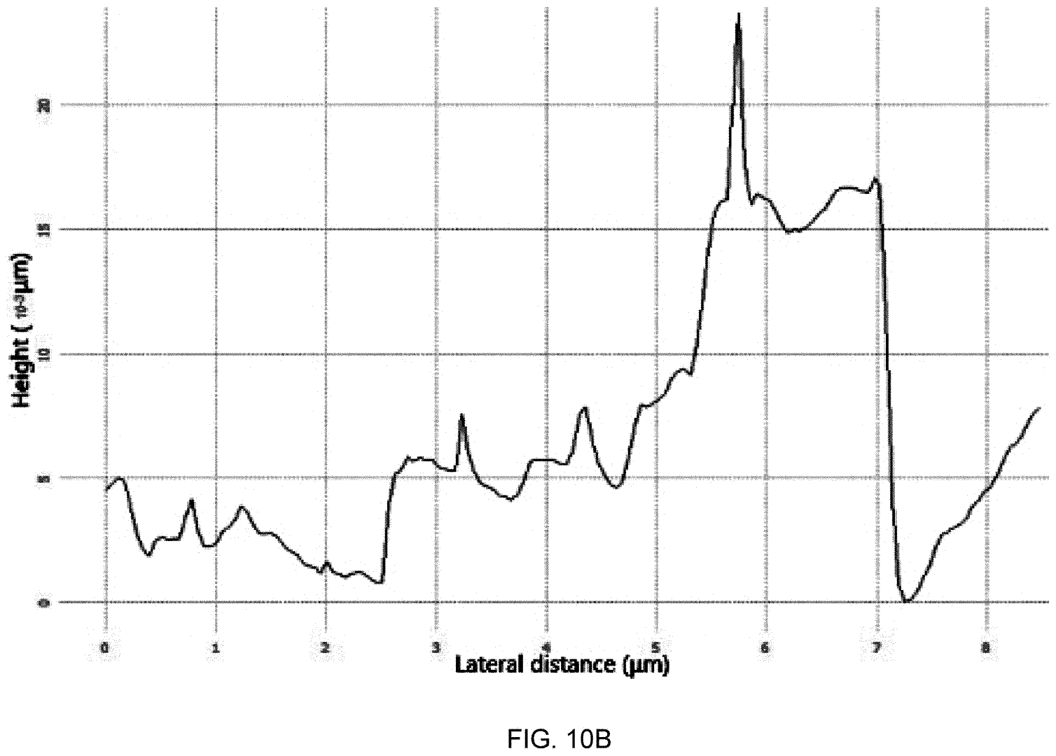

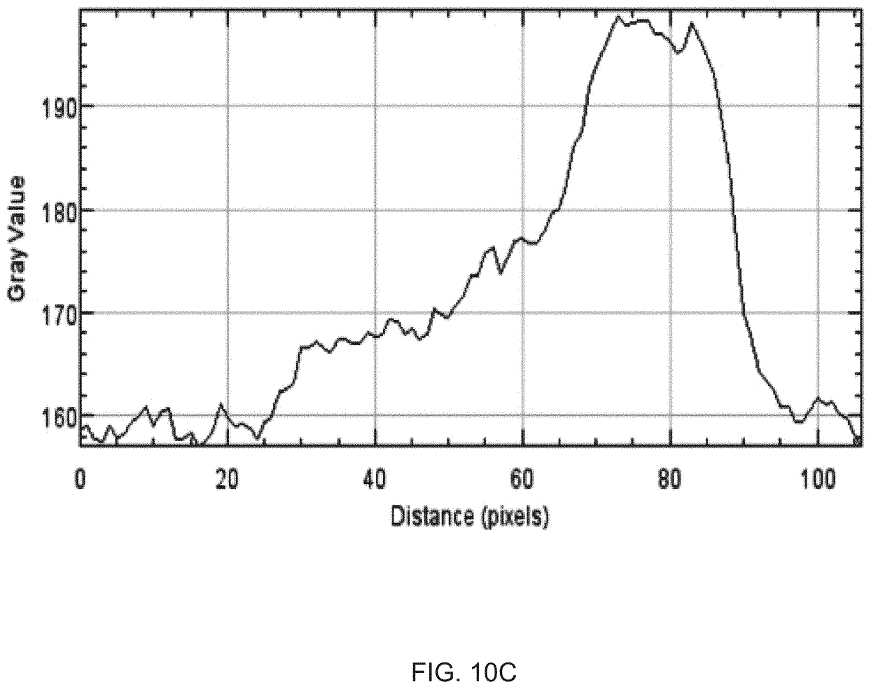

FIG. 10A-10 C show optical contrast measurements for MoTe₂ flake thickness determination. FIG. 10A shows an atomic force micrograph of two 1T′-MoTe₂ flakes exfoliated onto a PMN-PT substrate. The inset is an optical micrograph of the same area (all optical micrographs taken of flakes were taken with same brightness and exposure time.) FIG. 10B is a graph showing a height profile from the cross section in the AFM image from FIG. 10A. FIG. 10C is a graph showing contrast values of cross section in the optical micrograph presented in the inset of FIG. 10A. Combinations of AFM and contrast measurements of various 1T′-MoTe₂ flakes on PMN-PT were used to determine contrast values for various thicknesses.

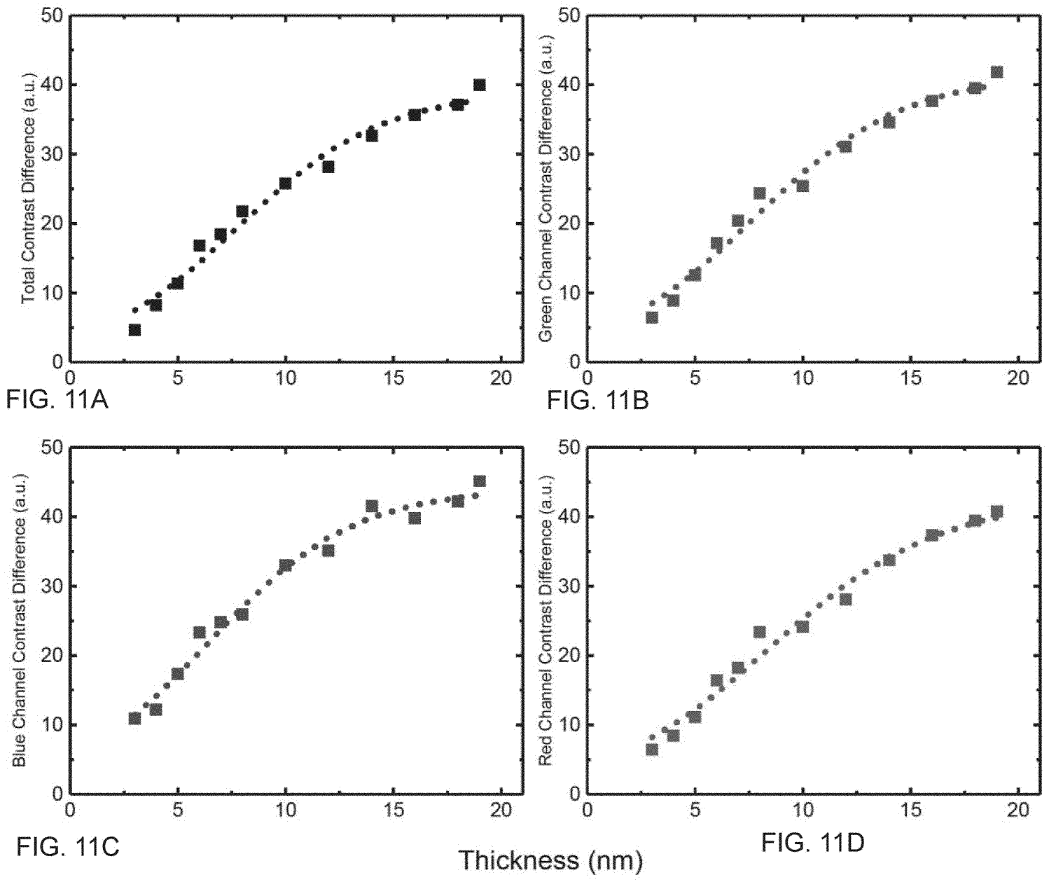

FIG. 11A-FIG. 11D show to optical contrast calibration measurements using ImageJ image analysis software. FIG. 11A is a graph showing a total contrast difference of a flake. FIG. 11B is a graph showing a green contrast difference of a flake. FIG. 11C is a graph showing a blue contrast difference of a flake. FIG. 11D is a graph showing a red contrast difference of a flake. The contrast of the substrate was found and then subtracted from the contrast value of the flake of interest. The contrast differences versus thicknesses were fitted to the Boltzmann function [38]. This function was then used to determine contrast values of various thicknesses (up to ˜20 nm). We did not use the function to extract thickness for any thicknesses larger than 20 nm since thicker flakes tended to reach the maximum contrast value of 255 somewhere shortly after 20 nm at our exposure level. All thicknesses determined from this method were then confirmed via resistivity and AFM measurements. For flakes above 20 nm, AFM was used to extract channel thickness.

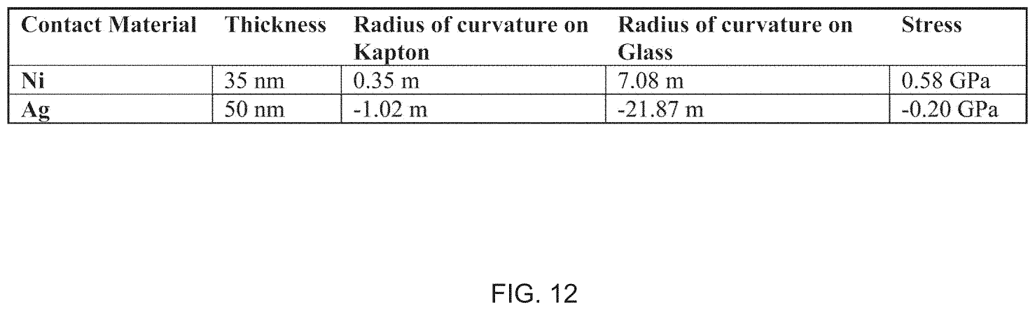

FIG. 12 is a Table 1 showing calculated stress values of deposited contact metals through wafer curvature methods. Films were deposited on large (>1 cm×1 cm) pieces of Kapton and glass cover slides, with the radius of curvature of the substrate measured using contact profilometry post-deposition. Stress values were then calculated using the Stoney equation [38-41] using mechanical properties of Kapton.

Phase transition devices and transistors as described herein can be formed on any suitable surface, such as, for example, any suitable substrate or any suitable film, such as a thin film.

Gate-controllable Switching of Optical Properties of MoTe2 from Ferroelectric Strain—Gate-controllable Switching of Optical Properties can be accomplished by a 1T′ to 2H phase change in 2 dimensional (2D) TMDC material that is heterointerfacially coupled to a ferroelectric oxide substrate. MoTe2 is one of the TMDCs that is close to a structural/optical phase transition.

A type of optical transistor comprising 2D channel (MoTe2) has been experimentally implemented on a ferroelectric substrate (PMN-PT). The phase of the MoTe2 of the exemplary device is controlled through ferroelectric strain to change from a semimetallic (1T′) phase to a semiconducting (2H) phase. This structural phase transition is also associated with changes in optical properties, such as having an optical gap (semiconducting) to not having a gap (semimetallic).

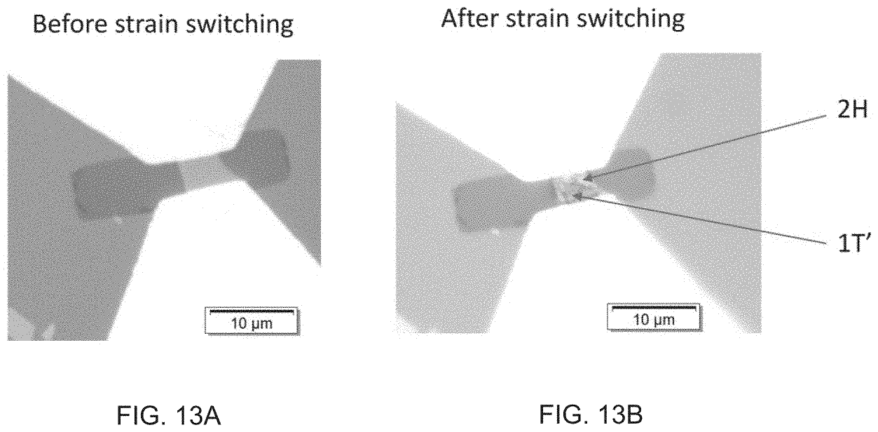

Such devices are non-volatile and can be reversed with gate controllable electric field, which controls the strain in the MoTe2 channel Because the strain from the ferroelectric substrate might not be enough to change the phase of the TMDC, we have devised a stress capping insulator layer to add a fixed amount of strain to the channel, while remaining transparent to probe optical properties (FIG. 13A).

The exemplary device was using 2D 1T′ MoTe2 (the metallic phase) covered by MgF2 as the stress capping layer. By sweeping the back-gate voltage, strain is produced in the ferroelectric substrate. Hence, the sum of strains from capping layer and the substrate, change the phase of some parts of the channel to 2H that is the semiconducting phase.

FIG. 13A is a photomicrograph of an exemplary gate controllable optical straintronic transistor before switching. Before switching, the straintronic transistor has a first optical property, such as being substantially optically opaque.

FIG. 13B is a photomicrograph of the optical straintronic transistor of FIG. 13A after switching. After switching, the straintronic transistor has a second optical property, such as being at least translucent. The difference in color under microscope illumination in FIG. 13B at the transistor is evidence of a change in optical properties. In both of FIG. 13A and FIG. 13B, the white regions are the pads.

The 1T′ and 2H phases can be easily distinguished in the channel. By engineering strain in the system, the optical properties of the materials can be changed by a large amount in a controlled fashion, opening the door to gate controllable optical and optoelectronic devices.

Nanoengineering the strain capping layers and the nanoscale ferroelectric domain structure of these devices can also lead to reconfigurable optical metamaterials, as well as other optical effects that arise from quantum confinement.

It is understood that the exemplary device can be used as an optoelectronic transistor. Such devices can be implemented in integrated structures such as planar optics. It is also understood that any suitable waveguides can be used to couple light to and from such gate controllable optical straintronic transistors.

Any software used to model and test the devices described hereinabove was provided or available on a computer readable non-transitory storage medium. A computer readable non-transitory storage medium as non-transitory data storage includes any data stored on any suitable media in a non-fleeting manner Such data storage includes any suitable computer readable non-transitory storage medium, including, but not limited to hard drives, non-volatile RAM, SSD devices, CDs, DVDs, etc.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

### REFERENCES

1. Zhirnov, V. V. & Cavin, R. K. Nanoelectronics: Negative capacitance to the rescue? Nat. Nanotechnol. 3, 77-78 (2008).
2. Cheung, K. P. On the 60 mV/dec @300 K limit for MOSFET subthreshold swing. in Proceedings of 2010 International Symposium on VLSI Technology, System and Application 72-73 (2010).
3. Chen, A. A review of emerging non-volatile memory (NVM) technologies and applications. Solid. State. Electron. 125, 25-38 (2016).
4. Frank, D. J. et al. Device scaling limits of Si MOSFETs and their application dependencies. Proc. IEEE 89, 259-288 (2001).
5. Pimbley, J. M. & Meindl, J. D. MOSFET scaling limits determined by subthreshold conduction. IEEE Trans. Electron Devices 36, 1711-1721 (1989).
6. Wilson, J. A. & Yoffe, A. D. The transition metal dichalcogenides discussion and interpretation of the observed optical, electrical and structural properties. Adv. Phys. 18, 193-335 (1969).
7. Tang, S. et al. Quantum spin Hall state in monolayer 1T′-WTe₂. Nat. Phys. 13, 683-687 (2017).
8. Gong, C. et al. Discovery of intrinsic ferromagnetism in two-dimensional van der Waals crystals. Nature 546, 265-269 (2017).
9. Huang, B. et al. Layer-dependent ferromagnetism in a van der Waals crystal down to the monolayer limit. Nature 546, 270-273 (2017).
10. Manzeli, S., Ovchinnikov, D., Pasquier, D., Yazyev, O. V. & Kis, A. 2D transition metal dichalcogenides. Nat. Rev. Mater. 2, 17033 (2017).
11. Akinwande, D., Petrone, N. & Hone, J. Two-dimensional flexible nanoelectronics. Nat. Commun. 5, 5678 (2014).
12. Duerloo, K.-A. N., Li, Y. & Reed, E. J. Structural phase transitions in two-dimensional Mo- and W-dichalcogenide monolayers. Nat. Commun. 5, 4214 (2014).
13. Song, S. et al. Room Temperature Semiconductor-Metal Transition of MoTe₂ Thin Films Engineered by Strain. Nano Lett. 16, 188-193 (2016).
14. Lee, M. L., Fitzgerald, E. A., Bulsara, M. T., Currie, M. T. & Lochtefeld, A. Strained Si, SiGe, and Ge channels for high-mobility metal-oxide-semiconductor field-effect transistors. J. Appl. Phys. 97, 11101 (2005).
15. Okino, H., Sakamoto, J. & Yamamoto, T. Cooling-Rate-Dependence of Dielectric Constant and Domain Structures in (1-x)Pb(Mg_{1/3}Nb_{2/3})O₃-x PbTiO₃ Single Crystals. Jpn. J. Appl. Phys. 44, 7160-7164 (2005).
16. Okino, H., Sakamoto, J. & Yamamoto, T. Cooling-Rate-Dependent Domain Structures of Pb(Mg_{1/3}Nb_{2/3})O₃—PbTiO₃ Single Crystals Observed by Contact Resonance Piezoresponse Force Microscopy. Jpn. J. Appl. Phys. 43, 6808-6811 (2004).
17. Gao, Y., Uchino, K. & Viehland, D. Effects of thermal and electrical histories on hard piezoelectrics: A comparison of internal dipolar fields and external dc bias. J. Appl. Phys. 101, 54109 (2007).
18. Ozgul, M., Trolier-McKinstry, S. & Randall, C. A. Influence of electrical cycling on polarization reversal processes in Pb(Zm_{1/3}Nb_{2/3})O₃—PbTiO₃ ferroelectric single crystals as a function of orientation. J. Appl. Phys. 95, 4296-4302 (2004).
19. Balke, N., Lupascu, D. C., Granzow, T. & Rodel, J. Fatigue of Lead Zirconate Titanate Ceramics. I: Unipolar and DC Loading. J. Am. Ceram. Soc. 90, 1081-1087 (2007).
20. Wu, S. Z. et al. Strain-mediated electric-field control of exchange bias in a Co₉₀Fe₁₀/BiFeO₃/SrRuO₃/PMN-PT heterostructure. Sci. Rep. 5, 8905 (2015).
21. Yang, L. et al. Bipolar loop-like non-volatile strain in the (001)-oriented Pb(Mg_{1/3}Nb_{2/3})O₃—PbTiO₃ single crystals. Sci. Rep. 4, 4591 (2015).
22. Zhao, P. et al. Domain engineered switchable strain states in ferroelectric (011) [Pb(Mg_{1/3}Nb_{2/3})O₃]₍₁₋ₓ₎—[PbTiO₃]ₓ (PMN-PT, x≈0.32) single crystals. J. Appl. Phys. 109, 124101 (2011).
23. Liu, M. et al. Non-volatile ferroelastic switching of the Verwey transition and resistivity of epitaxial Fe₃O₄/PMN-PT (011). Sci. Rep. 3, 1876 (2013).
24. Buzzi, M. et al. Single domain spin manipulation by electric fields in strain coupled artificial multiferroic nano structures. Phys. Rev. Lett. 111, 27204 (2013).
25. Cho, S. et al. Phase patterning for ohmic homojunction contact in MoTe₂. Science 349, 625-628 (2015).
26. Lin, Y.-F. et al. Ambipolar MoTe₂ Transistors and Their Applications in Logic Circuits. Adv. Mater. 26, 3263-3269 (2014).
27. Qu, D. et al. Carrier-Type Modulation and Mobility Improvement of Thin MoTe₂. Adv. Mater. 29, 1606433 (2017).
28. Fathipour, S. et al. Exfoliated multilayer MoTe₂ field-effect transistors. Appl. Phys. Lett. 105, 192101 (2014).
29. Roy, K. Ultra-Low-Energy Straintronics Using Multiferroic Composites. SPIN 3, 1330003 (2013).
30. Roy, K. Electric field-induced magnetization switching in interface-coupled multiferroic heterostructures: a highly-dense, non-volatile, and ultra-low-energy computing paradigm. J. Phys. D. Appl. Phys. 47, 252002 (2014).
31. Muller, J., Polakowski, P., Mueller, S. & Mikolajick, T. Ferroelectric Hafnium Oxide Based Materials and Devices: Assessment of Current Status and Future Prospects. ECS J. Solid State Sci. Technol. 4, N30-N35 (2015).
32. Hong, X. Emerging ferroelectric transistors with nanoscale channel materials: the possibilities, the limitations. J. Phys. Condens. Matter 28, 103003 (2016).
33. Manchanda, P., Sharma, V., Yu, H., Sellmyer, D. J. & Skomski, R. Magnetism of Ta dichalcogenide monolayers tuned by strain and hydrogenation. Appl. Phys. Lett. 107, 32402 (2015).
34. Xiang, H., Xu, B., Xia, Y., Yin, J. & Liu, Z. Strain tunable magnetism in SnX₂ (X=S, Se) monolayers by hole doping. Sci. Rep. 6, 39218 (2016).
35. Young, S. M. et al. Theoretical investigation of the evolution of the topological phase of Bi₂Se₃ under mechanical strain. Phys. Rev. B 84, 85106 (2011).
36. Xiang, H. et al. Quantum spin Hall insulator phase in monolayer WTe₂ by uniaxial strain. AIP Adv. 6, 95005 (2016).
37. Ge, Y., Wan, W., Yang, F. & Yao, Y. The strain effect on superconductivity in phosphorene: a first-principles prediction. New J. Phys. 17, 35008 (2015).
38. Zhang, H. et al. Optical thickness identification of transition metal dichalcogenide nanosheets on transparent substrates. Nanotechnology 28, 164001 (2017).
39. Janssen, G. C. A. M., Abdalla, M. M., van Keulen, F., Pujada, B. R. & van Venrooy, B. Celebrating the 100th anniversary of the Stoney equation for film stress: Developments from polycrystalline steel strips to single crystal silicon wafers. Thin Solid Films 517, 1858-1867 (2009).
40. Kim, J. S., Paik, K. W. & Oh, S. H. The multilayer-modified Stoney's formula for laminated polymer composites on a silicon substrate. J. Appl. Phys. 86, 5474 (1999).
41. Thomas, M. E., Hartnett, M. P. & McKay, J. E. The use of surface profilometers for the measurement of wafer curvature. J. Vac. Sci. Technol. A Vacuum, Surfaces, Film. 6, 2570-2571 (1988).

What is claimed is:

1. A phase transition device comprising:
a substrate or a thin film of a ferroelectric material; and
a transition metal dichalcogenide disposed over and in contact with said substrate or said thin film, said transition metal dichalcogenide having a semiconducting state and a semimetallic state, said semiconducting state or said semimetal state selectable by applying a voltage across said ferroelectric material to induce a strain in said transition metal dichalcogenide via said ferroelectric material.

2. The phase transition device of claim 1, comprising an electrical contact terminal disposed at either side of a strip of said transition metal dichalcogenide.

3. The phase transition device of claim 1, wherein said phase transition device is a field effect transistor.

4. The phase transition device of claim 3, wherein said transition metal dichalcogenide comprises a MoTe₂ material.

5. The phase transition device of claim 1, wherein said ferroelectric material comprises a single crystal of an oxide substrate of a relaxor ferroelectric material.

6. The phase transition device of claim 1, wherein said ferroelectric material comprises a PMN-PT material.

7. A plurality of phase transition devices according to claim 1 disposed in an integrated circuit.

8. The phase transition device of claim 1, wherein a non-volatile phase transition device remains in a previously selected state in an absence of electrical power.

9. A transistor device comprising:
a substrate or a thin film of a ferroelectric material having a first surface and a second surface;
a gate terminal electrically coupled to and disposed on said second surface; and
a section of a transition metal dichalcogenide disposed over and in contact with said substrate or said thin film, said section of a transition metal dichalcogenide having a source terminal at a first end of said section of a transition metal dichalcogenide and a drain terminal at a second end of said section of a transition metal dichalcogenide, said section of a transition metal dichalcogenide having a semiconducting state and a semimetallic state, said semiconducting state or said semimetallic state selectable by applying a voltage between said gate terminal and said source terminal or between said gate terminal and said drain terminal to induce a strain in said transition metal dichalcogenide via said ferroelectric material.

10. The transistor device of claim 9, wherein a non-volatile transistor device remains in a previously selected state in an absence of electrical power.

11. The transistor device of claim 9, wherein there is a substantially non-conducting path between said drain terminal and said source terminal in said semiconducting state.

12. The transistor device of claim 9, wherein there is a substantially conducting path between said drain terminal and said source terminal in said semimetallic state.

13. The transistor device of claim 9, wherein a phase transition device comprises a field effect transistor.

14. The transistor device of claim 9, wherein said transition metal dichalcogenide comprises a MoTe₂ material.

15. The transistor device of claim 9, wherein said ferroelectric material comprises a single crystal of an oxide substrate of a relaxor ferroelectric material.

16. The transistor device of claim 9, wherein said ferroelectric material comprises a PMN-PT material.

17. A plurality of transistor devices according to claim 9 disposed in an integrated circuit.

18. The transistor devices of claim 17, wherein said plurality of transistor devices comprise a sub nanosecond state change switching speed.

19. An integrated memory device comprising:
a substrate or a thin film of a ferroelectric material having a first surface and a second surface;
a plurality of non-volatile transistor devices which remain in a previously selected state in an absence of electrical power, each non-volatile transistor device comprising:
a gate terminal electrically coupled to and disposed on said second surface; and
a section of a transition metal dichalcogenide disposed over and in contact with said substrate or said thin film, said section of a transition metal dichalcogenide having a source terminal at a first end of said section of a transition metal dichalcogenide and a drain terminal at a second end of said section of a transition metal dichalcogenide, said section of a transition metal dichalcogenide having a semiconducting state and a semimetallic state, said semiconducting state or said semimetallic state selectable by applying a voltage between said gate terminal and said source terminal or between said gate terminal and said drain terminal to induce a strain in said transition metal dichalcogenide via said ferroelectric material.

20. A phase transition optical device comprising:
a substrate or a thin film of a ferroelectric material; and
a transition metal dichalcogenide disposed over and in contact with said substrate or said thin film, said transition metal dichalcogenide having a semiconducting state with a first optical property and a semimetallic state with a second optical property, said semiconducting state or said semimetal state selectable by applying a voltage across said ferroelectric material to induce a strain in said transition metal dichalcogenide via said ferroelectric material.

21. The phase transition optical device of claim 20, wherein said first optical property comprises a substantially opaque optical state, and said second optical property comprises an at least translucent optical state.
